(19) United States
(12) Patent Application Publication
(10) Pub. No.: US 2005/0074907 A1
(43) Pub. Date: Apr. 7, 2005

(54) Semi-conductor wafer fabrication

(76) Inventors: Adrian Kriz, Corvallis, OR (US); Michael Monroe, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/679,841

(22) Filed: Oct. 6, 2003

(51) Int. Cl. H01L 21/00

(52) U.S. Cl. 438/9

(57) ABSTRACT

A method of planarizing a semiconductor wafer includes applying a CMP process to a layer of dielectric material to planarize the wafer surface, and applying a plasma etching process to the wafer surface until a signal is generated from a detection layer that indicates that said detection layer has been removed from underlying features disposed on the water.

### BACKGROUND

Semiconductor wafers used in integrated circuits are commonly comprised of a plurality of layers of different materials stacked on top of each other. At a minimum, as shown in FIG. 1A, a semiconductor wafer 10 normally includes a base layer substrate 16, such as silicon (Si), covered by a layer of feature material 14, such as copper (Cu) or aluminum (Al), or some other metal. The feature layer 14 is formed to have various “features” 19 to implement the desired functionality of the integrated circuit. The features 19 are separated from one another by trenches, which are filled with a protective dielectric layer 18.

The manufacture of a semiconductor wafer as shown in FIG. 1A initially involves depositing or growing a “featureless” layer of feature material 14 on the substrate 16 (as shown in FIG. 1B). Then, the desired features are etched into the feature layer 14 using techniques known to those skilled in the art, including lithography, metal liftoff and silicon etching. The features 19 are separated by trenches 11. After the features are etched into the feature layer, a conformal layer of dielectric 18, such as, for example, silicon dioxide (SO₂), is deposited on the wafer 10. The dielectric 18 acts as an insulator and covers the tops of the features and fills in the trenches 11 that separate the features (as shown in FIG. 1D). As a result of this process, the upper surface of the dielectric layer 18 is generally non-planar and the top surfaces of the features are covered by the dielectric layer 18. Various planarization processes are used to planarize the dielectric layer 18 and to remove some of the dielectric layer so as to expose the top surfaces of the features 19, thereby creating a semiconductor wafer like that shown in FIG. 1A.

One known process for planarizing a semiconductor wafer is known as Chemical Mechanical Planarization (CMP). CMP generally consists of moving the semiconductor wafer across a polishing pad (sometimes made from a porous polymer), using a chemical slurry having suspended submicron-sized abrasive particles as a sort of “polish.” The chemical slurry interacts with the material being planarized to form a chemically-modified surface, and the suspended abrasive particles remove the chemically-modified material. The polishing pad ensures uniform slurry transport, distribution and removal of the reacted products, as well as uniform distribution of applied pressure across the wafer being planarized.

Current trends in integrated circuit manufacturing is to increase the number of features on a single semiconductor wafer, while, at the same time, increasing the size of the wafer. The increased size of semiconductor wafers, along with the desire to incorporate more and more “features” into the same wafer with progressively thinner thinfilm layers, causes various problems in the planarization process. One such problem is that it becomes more and more difficult to stop the CMP process at the most desirable point—where the dielectric layer 18 has been planarized and the top surfaces of the features 19 are exposed—without damaging the underlying features. A reason for this problem is there are often differences in hardness or chemical reactivity between the feature layer and the dielectric insulative layer. In the CMP process, this can lead to dishing of the dielectric layer or corrosion of the feature layer, either of which can potentially damage the semiconductor features. It is difficult to detect or predict when the CMP process should be stopped to avoid damaging the underlying features. This problem is amplified as the size of the features decrease to nano-scale, since the relatively smaller features cannot withstand as much contact from the CMP polishing pad. It is also made worse when the feature density across the die is not consistent, as isolated features tend to polish faster than dense features. The inventors hereof developed the described invention in light of these problems.

### BRIEF DESCRIPTION OF THE DRAWINGS

FIG. 1A illustrates an exemplary semiconductor wafer having a layer of feature material deposited on a substrate and a layer of dielectric filling in trenches between features.

FIG. 1B illustrates the exemplary semiconductor wafer of FIG. 1A at a stage of the fabrication process wherein a featureless layer of feature material is deposited onto a substrate.

FIG. 1C illustrates the exemplary semiconductor wafer of FIG. 1A at a stage of the fabrication process wherein features have been formed.

FIG. 1D illustrates the exemplary semiconductor wafer of FIG. 1A at a stage of the fabrication process wherein a layer of dielectric has been deposited over the features.

FIG. 2A illustrates a semiconductor wafer having a layer of feature material deposited on a substrate and a detection layer deposited on the feature layer, according to an embodiment of the invention.

FIG. 2B illustrates the semiconductor wafer of FIG. 2A at a stage of the fabrication process wherein features have been formed.

FIG. 2C illustrates the semiconductor wafer of FIG. 2B at a stage of the fabrication process wherein a layer of dielectric has been deposited over the feature layer and the detection layer.

FIG. 2D illustrates the semiconductor wafer of FIG. 2C at a stage of the fabrication process wherein the dielectric layer has been substantially planarized.

FIG. 2E illustrates the semiconductor wafer of FIG. 2D at a stage of the fabrication process wherein the dielectric layer has been removed to a point where it is substantially planar with the top surfaces of the detection layer.

FIG. 2F illustrates the semiconductor wafer of FIG. 2E at a stage of the fabrication process wherein the detection layer has been removed and the dielectric layer is substantially planar with the top surfaces of the features.

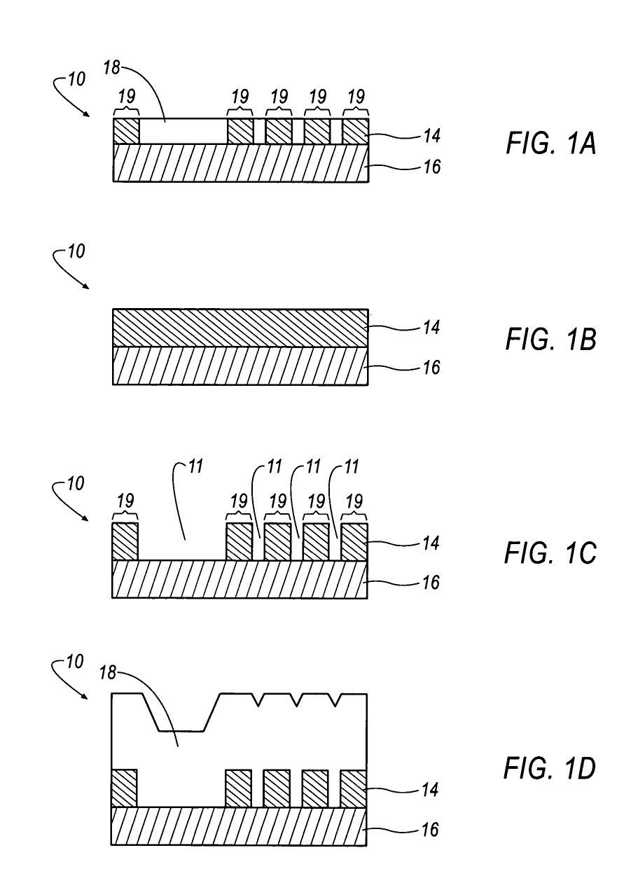

### DETAILED DESCRIPTION

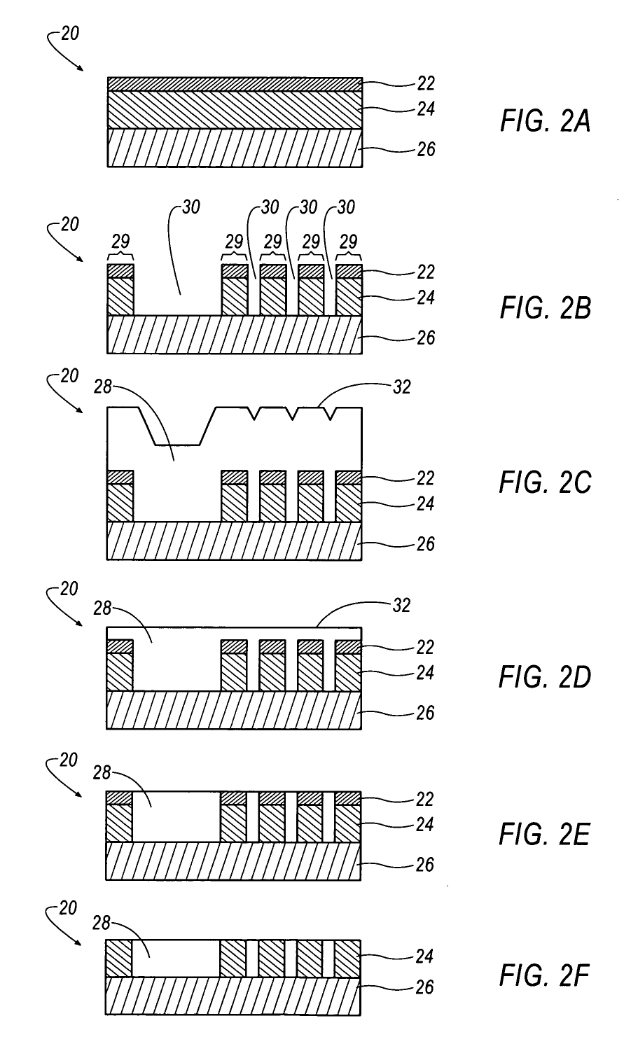

FIGS. 2A through 2F illustrate a semiconductor wafer at different stages of the fabrication process, according to an embodiment of the invention. As shown in FIG. 2A, the semiconductor wafer initially includes a layer of feature material 24 deposited on top of a base layer substrate 26. The base layer substrate may be comprised from various materials, including silicon (Si). The feature layer 24 may be comprised from various conductive materials, including, for example, aluminum (Al), copper (Cu), titanium (Ti), titanium nitride (TiN), tungsten (W), titanium tungsten (TiW), gold (Au), tantalum (Ta), tantalum aluminum (TaAl), and doped silicon (Si). In some embodiments, the feature layer 24 may also be comprised from various non-conductive materials on which features may be formed.

A layer of detection material 22 is deposited on top of the layer of feature material 24. The detection material can be various different types of materials, provided that it emits a detectable and identifiable signal when a plasma etching process is applied to it. In some embodiments, the material comprising the detection layer will be relatively harder than the underlying feature layer. As will be explained hereinafter, the detection layer facilitates detecting when the planarization process just reaches the top surface of the features before it damages the underlying features of the wafer. One possible detection layer material is silicon nitride (SiN), which forms a cyanide (CN) ion when a plasma etching process is applied to it. The cyanide ion emits an optical signal at approximately 388 nm.

FIG. 2B illustrates the semiconductor wafer of FIG. 2A with the features 29 having been formed. As shown, the features are separated by trenches 30, and each of the features 29 is “capped” by the detection layer 22. The features can be formed with known processes, including lithography, metal liftoff and silicon etching.

After the features 29 are formed, a thick layer of dielectric 28 is deposited on the wafer 20, as shown in FIG. 2C. The dielectric layer 28 may be comprised from various materials, including, for example, silicon dioxide (SiO₂), silicon nitride (SiN), tetraethylorthosilicate (TEOS), phosphosilicate glass (PSG), boro-PSG (BPSG), boron-phosphorous (BPTEOS), undoped-silica-glass (USG), thermal oxide (TOX), spin-on-glass (SOG), porous glasses, and various polymers. The layer of dielectric 28 covers the top surfaces of the detection layer “caps” 22 and fills in the trenches 30 separating the different features. The process of depositing the thick dielectric layer 28 onto the wafer results in a non-planar, “rough” top surface 32 (shown in FIG. 2C).

A CMP process is then used to planarize the non-planar top surface 32 of the dielectric layer 28. The CMP process is implemented until the top surface 32 of the dielectric layer 28 is substantially planar, as shown in FIG. 2D. The initial thickness of the dielectric layer 28 may be chosen so that a planar top surface 32 of the dielectric layer 28 can be achieved before the CMP process reaches the detection layer caps 22. In some embodiments, the thickness of the dielectric layer 28 is chosen so that planarization can be achieved using the CMP process while leaving at least 2000 angstroms of the dielectric layer 28 covering the detection layer caps 22.

Once planarization of the dielectric layer 28 is achieved, a plasma etching process is implemented to remove the remaining dielectric 28 and detection layer caps 22 so as to expose the tops of the features 24, while at the same time maintaining the planar nature of the dielectric layer 28. Accordingly, the wafer 20 is placed in a dielectric plasma etch chamber, and the wafer is etched using an argon (AR)/carbon tetrafluoride (CF4) plasma to remove the dielectric 28 and detection layer 22 to a level that exposes the tops of the features 24, while, at the same time, preserving the surface planarity achieved by the preceding CMP process by adjusting the plasma chemistry to achieve an approximately one to one ratio of the etch rates of the dielectric layer and the detection layer. FIG. 2E illustrates the wafer 20 during the plasma etching process, wherein the dielectric layer 28 above the detection layer caps 22 has been removed.

Once the plasma etching process removes the remaining dielectric layer 28 above the detection layer caps 22, the plasma etching process begins to remove the detection layer 22, which caps the features 24. While the detection layer 22 is undergoing the plasma etching process, optical emission data is provided in the form of an emitted cyanide wavelength. The cyanide wavelength is monitored during the plasma etching process. When the intensity of the cyanide wavelength changes (e.g., when the cyanide wavelength associated with the implemented detection layer is no longer present), it is determined that the detection layer caps 22 have been completely removed, and that the top surface of the features 24 are now exposed. By closely monitoring the intensity level of the cyanide wavelength, the plasma etching process can be accurately terminated when the intensity of the cyanide wavelength changes, which represents the time when the detection layer caps 22 have been removed, but before any appreciable amount of feature material has been removed from the feature material layer 24. FIG. 2F illustrates the wafer 20 after the detection layer caps 22 have been removed via the plasma etching process.

The described embodiment provides an improved method of planarizing a semiconductor wafer and exposing the top surfaces of the features without damaging the features, as is possible when a CMP process alone is used to planarize a semiconductor wafer.

While the present invention has been particularly shown and described with reference to the foregoing preferred and alternative embodiments, it should be understood by those skilled in the art that various alternatives to the embodiments of the invention described herein may be employed in practicing the invention without departing from the spirit and scope of the invention as defined in the following claims. It is intended that the following claims define the scope of the invention and that the method and apparatus within the scope of these claims and their equivalents be covered thereby. This description of the invention should be understood to include all novel and non-obvious combinations of elements described herein, and claims may be presented in this or a later application to any novel and non-obvious combination of these elements. The foregoing embodiments are illustrative, and no single feature or element is essential to all possible combinations that may be claimed in this or a later application. Where the claims recite “a” or “a first” element of the equivalent thereof, such claims should be understood to include incorporation of one or more such elements, neither requiring nor excluding two or more such elements. Further, the use of the words “first”, “second”, and the like do not alone imply any temporal order to the elements identified. The invention is limited only by the following claims

1. A method of fabricating a semiconductor wafer, comprising:
depositing a detection layer of material over a layer of feature material;
forming features in said feature material layer and said detection layer;
depositing a layer of dielectric over the wafer;
applying a CMP process to said wafer until said dielectric layer is planarized;
applying a plasma etching process to said wafer until said detection layer is removed to a level where said features are exposed; and
monitoring an optical signal during said plasma etching process, said optical signal being generated from the application of said plasma etching process to said detection aver.

2. The method of claim 1, wherein said CMP application step is stopped while a portion of said dielectric layer remains above said detection layer.

3. The method of claim 2, further comprising the step of adjusting said plasma etching process to achieve an approximately one to one ratio of etch rates of said dielectric layer and said detection layer.

4. The method of claim 2, wherein said remaining portion of said dielectric layer is at least 2000 Angstroms thick.

5. The method of claim 1, wherein said detection layer is completely removed by said plasma etching process.

6. The method of claim 1, further comprising the step of stopping said plasma etching process when said optical signal indicates that said detection layer has been removed from said feature material layer.

7. The method of claim 1, wherein said optical signal is a cyanide wavelength produced when said plasma etching process is applied to said detection layer.

8. The method of claim 1, wherein said detection layer is comprised of silicon nitride.

9. The method of claim 1, wherein said detection layer is comprised of a material that is harder than said feature material.

10. The method of claim 1, wherein said feature material is a conductive material.

11. A semiconductor wafer, comprising:
a plurality of features formed in a layer of feature material on a substrate, each of the features having an upper surface;
a layer of detection material capping each of said upper surfaces of said features; and
a layer of dielectric deposited onto said substrate and said detection layer.

12. The semiconductor wafer of claim 11, wherein said detection layer is comprised of a material that is harder than said feature material.

13. The semiconductor wafer of claim 11, wherein said detection layer is comprised of silicon nitride.

14. The semiconductor wafer of claim 11, wherein:
an optical signal having a first identifiable intensity level is generated when a plasma etching process is applied to said detection layer;
a second identifiable intensity level of said optical signal is generated when the plasma etching process is applied to said feature; and
said first identifiable intensity level is different than said second identifiable intensity level.

15. An integrated circuit, comprising:
a plurality of features separated by trenches, each said features having a top surface;
a layer of dielectric deposited in said trenches and substantially planar with said top surfaces of said feature, said planar nature of said dielectric layer and said top surfaces of said feature being achieved by a planarization process that includes plasma etching a layer of detection material capping said feature until it is determined that said detection layer has been removed from the feature.

16. The integrated circuit of claim 15, wherein said planarization process includes applying a CMP process to said dielectric layer before applying said plasma etching process.

17. The integrated circuit of claim 15, wherein said features are comprised of conductive material.

18. A method of planarizing a semiconductor wafer, comprising:
applying a CMP process to a layer of dielectric material at least until said dielectric layer is approximately planar; and
applying a plasma etching process to a detection layer of material until a signal is generated from said plasma etching process that indicates that said detection layer has been removed from underlying features.

19. The method of claim 18, wherein said signal is a change in an intensity level of a cyanide wavelength generated by said plasma etching process.

20. The method of claim 19, wherein said CMP process is stopped while a layer of dielectric remains covering said detection layer; and wherein said plasma etching process begins while said dielectric layer remains covering said detection layer.

21. A method of removing dielectric material from a semiconductor wafer that has been previously planarized using a CMP process, comprising the step of applying a plasma etching process to a detection layer of material until an identifiable signal is generated from said plasma etching process that indicates that said detection layer has been substantially removed from underlying features disposed on the wafer.

22. The method of claim 21, wherein said signal is a change in an intensity level of a cyanide wavelength generated by said plasma etching process.

23. The method of claim 21, wherein said CMP process is stopped while a layer of dielectric remains covering said detection layer; and wherein said plasma etching process begins while said dielectric layer remains covering said detection layer.
